(19) United States
(12) Patent Application Publication
(10) Pub. No.: US 2009/0224792 A1
(43) Pub. Date: Sep. 10, 2009

(54) METHOD TO REDUCE TEST PROBE DAMAGE FROM EXCESSIVE DEVICE LEAKAGE CURRENTS

(75) Inventors: Jeanne Paulette Spence Bickford, Essex Junction, VT (US); Nazmul Habib, South Burlington, VT (US); Robert McMahon, Essex Junction, VT (US)

Correspondence Address: WOOD, HERRON & EVANS, LLP (IBM-BUR), 2700 CAREW TOWER, 441 VINE STREET, CINCINNATI, OH, 45202, US

(73) Assignee: INTERNATIONAL BUSINESS MACHINES CORPORATION, Armonk, NY (US)

(21) Appl. No.: 12/041,826

(22) Filed: Mar. 4, 2008

(51) Int. Cl. G01R 31/26; G01R 31/303

(52) U.S. Cl. 324/765; 702/117

(57) ABSTRACT

A method is provided for predicting leakage current in a semiconductor die with a plurality of devices. A limited leakage macro is incorporated on the semiconductor die. The limited leakage macro is initially tested to measure a leakage current before testing devices outside the limited leakage macro. The measured leakage current is compared to a threshold value for the leakage current. If the leakage current exceeds the threshold value, probe testing is terminated. If, however, the leakage current does not exceed the threshold value, testing continues for devices outside of the limited leakage macro.

### FIELD OF THE INVENTION

The present invention is related to methods for predicting leakage current in integrated circuit devices during probe testing to reduce leakage induced probe damage.

### BACKGROUND OF THE INVENTION

Semiconductor technologies beyond 130 nm have high levels of leakage currents, which may result in test probe damage during testing. For example, for a 130 nm technology node, leakage components of chip power may be about 10 to about 20 percent of total power. As the technologies get smaller, the observed leakage currents become higher and less predictable. At 90 nm, the leakage currents may dissipate about 25 to about 50 percent of total power and at 65 nm, the leakage currents may dissipate about 25 to about 65 percent of total power. Test probe damage is more likely with the technologies characterized by the higher leakage levels as the margin between expected leakage and leakage that damages test probes narrows for the newer technologies. As technologies get smaller, more complex and costly test probes are needed to test dies made with these technologies.

Earlier technologies used a gross current limit designed to identify defect related currents. This gross “stop test” mechanism, however, does not work for sub 180 nm technologies. Systematic levels of leakage may damage a test probe before traditional “probe melt” controls are able to shut down a test. Contemporary practice, when applied to newer technologies, typically identifies probe leakage issues after the test probe is badly damaged.

Damage to the test probe may occur in two varieties. First, the probe may be very badly damaged and stop working, necessitating replacement or repair, which results in added cost. Alternately, the test probe may be damaged, but still functional, which results in inaccurate measurements. This may be more problematic because noncompliant chips may be passed and forwarded on to customers. Additionally, malfunctioning probes may falsely indicate that compliant chips are noncompliant, causing the compliant chips to be scrapped, also adding cost because of the resultant yield loss.

What is needed therefore is a method to predict leakage currents on a chip that protects test probes from damage arising from excessive leakage currents.

### SUMMARY OF THE INVENTION

A method is provided for predicting leakage current in a semiconductor product die with a plurality of devices. The method incorporates a limited leakage macro on the semiconductor die. Leakage current is measured for the limited leakage macro, which is then compared to a threshold value for the leakage current that may cause test probe damage. Probe testing is terminated if the leakage current exceeds the threshold value. Probe testing of devices on other regions of the chip is continued if the leakage current does not exceed the threshold value.

In some embodiments, the limited leakage macro includes an isolated subset of the plurality of devices. This subset of the plurality of devices may include the devices having the highest expected leakage. The measured leakage current for the subset is below a threshold value for a test probe. The limited leakage macro may be incorporated on the semiconductor die in a potential problematic area.

In other embodiments, a database is provided containing maximum leakage values per product, where the product content is by FET type. In some embodiments, comparing the measured leakage current to the expected value is accomplished by scaling the measured leakage current by the plurality of devices on the semiconductor die, retrieving a maximum leakage value for a product from the database, and comparing the scaled leakage current to the maximum leakage value from the database. The semiconductor die may be scrapped if the leakage current exceeds that expected value.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIG. 1 is a flowchart illustrating the use of limited leakage macros for predicting leakage currents.

FIG. 2 is a block diagram of an embodiment of a system to implement the method of the flowchart in FIG. 1.

### DETAILED DESCRIPTION

Embodiments of the invention provide a method for predicting a leakage current on semiconductor chip or die prior to full probe testing in order to minimize probe damage from leakage currents. Some embodiments implement a limited leakage macro, which contains a representative subset of the devices on the die. Leakage currents are measured on the limited leakage macro, which may be proportionately small and within safe limits for the test probe. These leakage measurements may then be scaled appropriately for the chip configuration to predict the leakage current for the chip. Based on the predicted leakage current, a decision may then be made to continue with the probe testing, or to terminate the test and scrap the die.

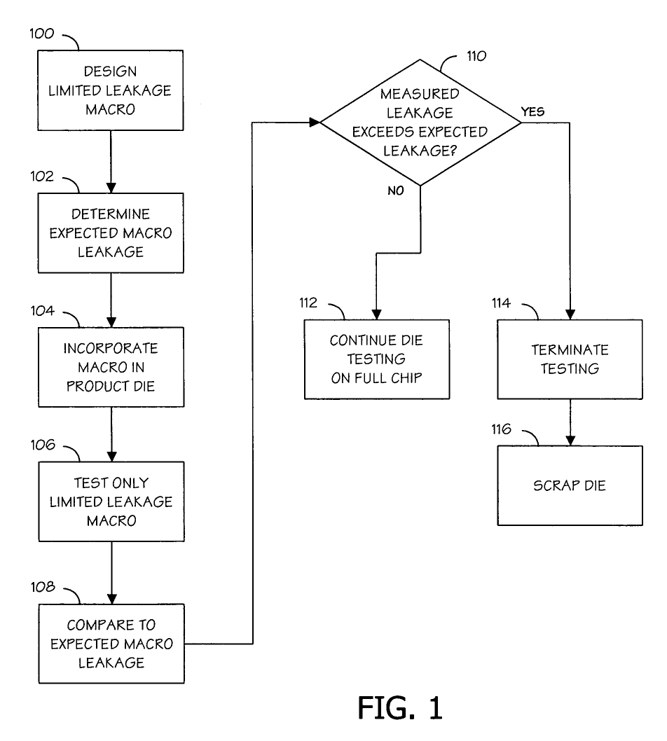

Turning now to the drawings, wherein like numbers denote like parts throughout the several views, FIG. 1 is a flowchart of the process consistent with one embodiment of the invention. The limited leakage macro is designed in block 100. In designing the macro, a small number of representative devices is selected from the entire chip design and isolated from the rest of the chip. Leakage measurements from these representative devices will later be scaled to predict the leakage for the entire chip. It will be apparent to one skilled in the art that care should be taken in selecting the subset of the devices to ensure there is adequate or proportional representation. Once the limited leakage macro has been designed, an expected leakage current is determined in block 102. Because of the small area and limited number of devices in the limited leakage macro, the leakage currents will be proportionately small. These leakage currents should be small enough to be within the safe range of the test probe.

After the limited leakage macro has been designed and the leakage currents determined, the macro is then implemented into each of the product designs in block 104. The limited leakage macro may be implemented using several different methods. For example, in one embodiment, the limited leakage macro may be incorporated on the chip with a dedicated I/O that is directly coupled with the macro. In an alternate embodiment, the macro may share I/O with a ring oscillator used for performance screening. This implementation may need additional control logic, which may be implemented during the design of the chip. In another embodiment, the limited leakage macro may be implemented in a scalable parametric macro (SPM) with a dedicated controlled current source. This implementation may also require a dedicated I/O for the current source.

In yet another embodiment, the limited leakage macro may be implemented in an SPM with a shared controlled current source that already exists within the chip. This implementation may provide for measuring the macro plus the background surroundings. The background surroundings may then be subtracted to provide the measured values of the macro. This implementation may have more inaccuracy than the other implementations, but it also may require the least amount of overhead and may also be adequate to protect the test probe against damage. In a specific alternate embodiment of this method, fuses may be excluded when implementing the method. Of course, one of ordinary skill in the art would realize that there are additional alternative methods to implement the limited leakage macro on the chip and still be consistent with the methodology provided above.

Multiple chips are fabricated on a wafer by fabrication processes familiar to a person having ordinary skill in the art of device fabrication. Each of the chips, which are nominally identical, carries one of embodiments of the limited leakage macro, which has been incorporated into the chip design. The term “chip” is considered herein to be synonymous with, and is used interchangeably with, the terms “integrated circuit” and “die”. As explained below, the limited leakage macro may be placed in an identified or suspected problematic area of each chip.

At wafer test, the test probe begins by testing only the limited leakage macro in block 106. In some embodiments, multiple limited leakage macros may be implemented for each type of device expected to significantly impact die level leakage in the product design. Each of these macros may be tested by the test probe prior to full chip testing. Wafer probing involves positioning needle-like test probes onto external interconnects (probe pads or bond pads) on each chip fabricated on a wafer and testing the limited leakage macro on each of the chips using various electronic signals supplied through the probes. A stepper moves the test probes to different chip locations on the wafer, establishes conductive contact between the probes and the external interconnects for that chip location, and conducts electrical testing of the limited leakage macro at each chip location. Leakage currents measured from the macro(s) are then compared to a pass/fail or threshold leakage current for the limited leakage macro in block 108.

A limited leakage macro that draws more current than a threshold value of the leakage current for any input test vector is declared defective by the testing. A limited leakage macro that draws less current than the threshold value of the leakage current is considered non-defective. The threshold value for the leakage current is set such that a limited leakage macro that contains defects or manufacturing process excursions is considered defective and fails the test, and a limited leakage macro that is free of defects passes the test. If the measured leakage does not exceed the threshold leakage current (“No” branch of decision block 110), then probe testing continues on the die in block 112 to test devices that are on regions of the die outside of the limited leakage macro. The stepper then automatically moves the test probes to another chip location on the wafer, conducts testing of the limited leakage macro at that chip location and determines whether to execute a full chip test based upon the leakage current measured from the limited leakage macro, and then repeats the same steps again for other chip locations on the wafer. However, if the measured leakage does exceed the threshold leakage current (“Yes” branch of decision block 110), then the probe testing is terminated in block 114 and the die failing the test may be scrapped in block 116. Further, this technique can be used to reduce test time by applying criteria whereby if the number of observed fails exceeds the number of allowed fails per wafer or per region of a wafer, the entire wafer or region of the wafer is dispositioned as scrap.

In one embodiment, the limited leakage macro fabricated on each of the die may be tested using quiescent current supply (IDDQ) testing, which is an accepted technique for testing complementary-metal-oxide-semiconductor (CMOS) integrated circuits for the presence of manufacturing faults. IDDQ testing relies on measuring the supply current (Idd) in the quiescent state when the devices of the limited leakage macro are idle and not switching. Fault-free CMOS devices in the limited leakage macro consume very little current while in the quiescent state with the clock stopped. In contrast, many common manufacturing faults and process executions will cause the observable leakage current of defective devices in the limited leakage macro to increase by orders of magnitude, which can increase the sensitivity of IDDQ testing and promote detection of limited leakage macros with an excessively high leakage current that exceed the threshold leakage current.

Placement of the limited leakage macro on the chips may also be considered as part of the design and testing. Instead of placing the limited leakage macro in a “default” location, the limited leakage macro may be placed in an identified or suspected problematic area of the chip. For example, the limited leakage macro may be placed in a variety of different design environments such as different densities (example: polysilicon density), big isolated shapes, adjacent to SRAMs, etc. Additionally, parameter values based on the layout environment design rules may be specified and used by designers. The representative layout environments may then be monitored in manufacturing using the on-chip parametric macros to ensure compliance with the parametric layout design rules. This allows for feedback to manufacturing that identifies potential problem areas found in the leakage testing.

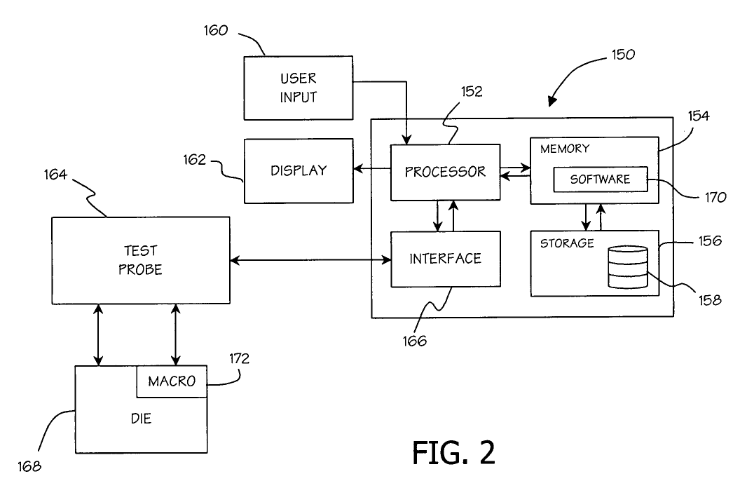

FIG. 2 shows an exemplary hardware and software environment for an apparatus 150 suitable for predicting leakage currents in a manner consistent with the invention. For the purposes of the invention, apparatus 150 may represent practically any computer, computer system, or programmable device, e.g., multi-user or single-user computers, desktop computers, portable computers and devices, handheld devices, network devices, mobile phones, etc. Apparatus 150 will hereinafter be referred to as a “computer” although it should be appreciated that the term “apparatus” may also include other suitable programmable electronic devices.

Computer 150 typically includes at least one processor 152 coupled to a memory 154. Processor 152 may represent one or more processors (e.g. microprocessors), and memory 154 may represent the random access memory (RAM) devices comprising the main storage of computer 150, as well as any supplemental levels of memory, e.g., cache memories, non-volatile or backup memories (e.g. programmable or flash memories), read-only memories, etc. In addition, memory 154 may be considered to include memory storage physically located elsewhere in computer 150, e.g., any cache memory in a processor 152, as well as any storage capacity used as a virtual memory, e.g., as stored on a mass storage device 156 or another computer coupled to computer 150 via a network. The mass storage device 156 may contain a include databases 158, which may contain leakage for each product created, for example by a leakage sizing tool.

Computer 150 also typically receives a number of inputs and outputs for communicating information externally. For interface with a user or operator, computer 150 typically includes one or more user input devices 160 (e.g., a keyboard, a mouse, a trackball, a joystick, a touchpad, a keypad, a stylus, and/or a microphone, among others). Computer 150 may also include a display 162 (e.g., a CRT monitor, an LCD display panel, and/or a speaker, among others). The interface to computer 150 may also be through an external terminal connected directly or remotely to computer 150, or through another computer communicating with computer 150 via a network, modem, or other type of communications device. Computer 150 may also communicate with the test probe 164 through interface 166 during testing of the die 168.

Computer 150 generally operates under the control of an operating system, and executes or otherwise relies upon various computer software applications, components, programs, objects, modules, data structures, etc. (e.g. software 170 implementing the leakage sizing tool). The software 170 implementing the leakage sizing tool may be configured to scale up the leakages measured on the macro and compare those values against values stores in the database 158.

The database 158, as stated above, may contain maximum leakage values for each of the products. The data in database 158 may organized in some embodiments by FET type. Power estimations from power spreadsheets may also be incorporated in database 158 or in other embodiments, may be separately stored and accessed from database 158. Software 170 working in conjunction with the test probe 164 and referencing database 158 may be implemented to make the determination if probe testing should continue or be stopped. For example, the software 170 may be configured to scale the leakage from the limited leakage macro proportionately by the content of the chip. The software 170 may then compare this scaled leakage value against the maximum expected leakage for a product stored in database 158.

In general, the routines executed to implement the embodiments of the invention, whether implemented as part of an operating system or a specific application, component, program, object, module or sequence of instructions will be referred to herein as “computer program code”, or simply “program code”. The computer program code typically comprises one or more instructions that are resident at various times in various memory and storage devices in a computer, and that, when read and executed by one or more processors in a computer, causes that computer to perform the steps necessary to execute steps or elements embodying the various aspects of the invention. Moreover, while the invention has and hereinafter will be described in the context of fully functioning computers and computer systems, those skilled in the art will appreciate that the various embodiments of the invention are capable of being distributed as a program product in a variety of forms, and that the invention applies equally regardless of the particular type of computer readable media used to actually carry out the distribution. Examples of computer readable media include but are not limited to physical, recordable type media such as volatile and non-volatile memory devices, floppy and other removable disks, hard disk drives, optical disks (e.g., CD-ROM's, DVD's, etc.), among others, and transmission type media such as digital and analog communication links.

In addition, various program code described herein may be identified based upon the application or software component within which it is implemented in specific embodiments of the invention. However, it should be appreciated that any particular program nomenclature is merely for convenience, and thus the invention should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, APIs, applications, applets, etc.), it should be appreciated that the invention is not limited to the specific organization and allocation of program functionality described herein.

Those skilled in the art will recognize that the exemplary environment illustrated in FIG. 2 is not intended to limit the present invention. Indeed, those skilled in the art will recognize that other alternative hardware and/or software environments may be used without departing from the scope of the invention.

This method presented above allows tests to be terminated before probe damage occurs. With probes avoiding damage, damage related yield loss does not occur. Additionally cost associated with repairing or replacing damaged probes is avoided. This method may be used for wafer test on any semiconductor integrated circuit product.

While all of the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the spirit or scope of the applicant's general inventive concept.

What is claimed is:

1. A method for predicting leakage current in a semiconductor die with a plurality of devices, the method comprising:
incorporating a limited leakage macro on the semiconductor die;
initially testing the limited leakage macro to measure a leakage current before testing devices outside the limited leakage macro;
comparing the measured leakage current to a threshold value for the leakage current;
if the leakage current exceeds the threshold value, terminating probe testing; and
if the leakage current does not exceed the threshold value, continuing testing of the devices outside of the limited leakage macro.

2. The method of claim 1 wherein limited leakage macro includes an isolated subset of the plurality of devices.

3. The method of claim 2 wherein the subset of the plurality of devices includes the devices having the highest expected leakage.

4. The method of claim 1 further comprising:
providing a database containing maximum leakage values per product,
wherein a product content is by FET type.

5. The method of claim 4 wherein comparing the measured leakage current to the expected value comprises:
scaling the measured leakage current by the plurality of devices on the semiconductor die;
retrieving a maximum leakage value for a product from the database; and
comparing the scaled leakage current to the maximum leakage value from the database.

6. The method of claim 1 further comprising:
scrapping the semiconductor die if the leakage current exceeds the threshold value; and
scrapping the entire wafer or region of the wafer if the number of observed fails exceeds the number of allowed fails for a wafer or region of a wafer.

7. The method of claim 1 wherein the measured leakage current for the limited leakage macro is below a threshold value for a test probe.

8. The method of claim 1 wherein the limited leakage macro is incorporated on the semiconductor die in a potential problematic area.
